(19) United States
(12) Patent Application Publication
(10) Pub. No.: US 2018/0137805 A1
(43) Pub. Date: May 17, 2018

(54) DISPLAY PANEL, DISPLAY DEVICE AND SCAN DRIVING METHOD

(71) Applicant: XIAMEN TIANMA MICRO-ELECTRONICS CO., LTD., Xiamen (CN)

(72) Inventors: Zhiwei Zheng, Xiamen (CN); Zhipeng Huang, Xiamen (CN); Kangpeng Yang, Xiamen (CN); Yumin Xu, Xiamen (CN)

(73) Assignee: XIAMEN TIANMA MICRO-ELECTRONICS CO., LTD., Xiamen (CN)

(21) Appl. No.: 15/867,704

(22) Filed: Jan. 11, 2018

(30) Foreign Application Priority Data
Sep. 14, 2017 (CN) 201710826757.X

(51) Int. Cl. G09G 3/20; G11C 19/28

(52) U.S. Cl. CPC G09G 3/2092; G09G 2310/0286; G09G 2330/021; G11C 19/28

(57) ABSTRACT

A display panel, display device and scan driving method, display panel has first display area and second display area protruding from first display area, display panel includes: display unit placed in both first and second display area; second scan driving circuit corresponding to second display area, including cascaded multiple stages of shift registers, output end of each stage of shift register of second scan driving circuit being electrically connected with display unit in second display area; first scan driving circuit corresponding to first display area, including cascaded multiple stages of shift registers, output end of each stage of shift register of first scan driving circuit being electrically connected with display unit in first display area; control unit, first shift register of second scan driving circuit being cascaded with second shift register of first scan driving circuit via control unit controlling connection/disconnection between first and second shift register.

### CROSS-REFERENCE TO RELATED APPLICATIONS

The present application claims priority to Chinese Patent Application No. 201710826757.X, filed on Sep. 14, 2017, the content of which is incorporated herein by reference in its entirety.

### TECHNICAL FIELD

The present disclosure relates to the field of display technologies and, in particular, to a display panel, a display device and a scan driving method.

### BACKGROUND

As for the current display device such as cellphone, in order to realize corresponding functions, elements such as camera or receiver are disposed outside the display panel. In order to increase the screen occupancy ratio of the display device, a groove structure is formed on the display panel, and the elements such as camera or receiver are disposed in the groove.

However, the increase in the screen occupancy ratio enlarges the area of the display area, thereby resulting in an increase in power consumption.

### SUMMARY

The present disclosure provides a display panel, a display device and a scan driving method, capable of decreasing the display power consumption.

In one aspect, the present disclosure provides a display panel having a first display area and a second display area protruding from the first display area, including: a display unit placed in both the first display area and the second display area; a first scan driving circuit corresponding to the first display area, the first scan driving circuit comprising cascaded multiple stages of shift registers, and an output end of each stage of shift register of the first scan driving circuit being electrically connected with the display unit in the first display area; a second scan driving circuit corresponding to the second display area, the second scan driving circuit comprising cascaded multiple stages of shift registers, and an output end of each stage of shift register of the second scan driving circuit being electrically connected with the display unit in the second display area; and a control unit, a first shift register of the second scan driving circuit being cascaded with a second shift register of the first scan driving circuit via the control unit, and the control unit being configured to control connection/disconnection between the first shift register and the second shift register.

In another aspect, the present disclosure provides a display device including the display panel described above.

In another aspect, the present disclosure provides a scan driving method for the above display panel, the method includes: controlling, by the control unit in a first display mode, the first shift register to be in conduction with the second shift register; controlling, by the control unit in a second display mode, the first shift register not to be in conduction with the second shift register.

As for the display panel, display device and scan driving method in the embodiments of the present disclosure, the first shift register of the second scan driving circuit is cascaded with the second shift register of the first scan driving circuit, in the normal display mode, the control unit controls to allow the first shift register to be in conduction with the second shift register, so that the second scan driving circuit and the first scan driving circuit together complete scanning of the second display area and the first display area, in a display mode with low power consumption, the control unit controls to make the first shift register not in conduction with the second shift register, so that the second scan driving circuit individually completes scanning of the second display area, and it may not trigger operation of the first scan driving circuit, thereby decreasing the power consumption of the display panel.

### BRIEF DESCRIPTION OF DRAWINGS

In order to more clearly illustrate technical solutions in embodiments of the present disclosure or in the related art, the accompanying drawings used in the embodiments and in the related art are briefly introduced as follows. Obviously, the drawings described as follows are merely part of the embodiments of the present disclosure, other drawings can also be acquired by those skilled in the art without paying creative efforts.

FIG. 1 is a structural schematic diagram of a display panel according to an embodiment of the present disclosure;

FIG. 2 is a schematic diagram of a connection of a scan driving circuit in FIG. 1;

FIG. 3 is a schematic diagram of another connection of the scan driving circuit in FIG. 1;

FIG. 4 is a structural schematic diagram of another display panel according to an embodiment of the present disclosure;

FIG. 5 is a structural schematic diagram of still another display panel according to an embodiment of the present disclosure;

FIG. 6 is a structural schematic diagram of still another display panel according to an embodiment of the present disclosure;

FIG. 7 is a structural schematic diagram of still another display panel according to an embodiment of the present disclosure;

FIG. 8 is a structural schematic diagram of still another display panel according to an embodiment of the present disclosure;

FIG. 9 is a structural schematic diagram of still another display panel according to an embodiment of the present disclosure;

FIG. 10 is a structural schematic diagram of a display device according to an embodiment of the present disclosure;

FIG. 11 is a sequence diagram of a control signal of a control unit according to an embodiment of the present disclosure; and

FIG. 12 is another sequence diagram of a control signal of a control unit according to an embodiment of the present disclosure.

### DESCRIPTION OF EMBODIMENTS

The terms used in the embodiments of the present disclosure are merely for the purpose of describing embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

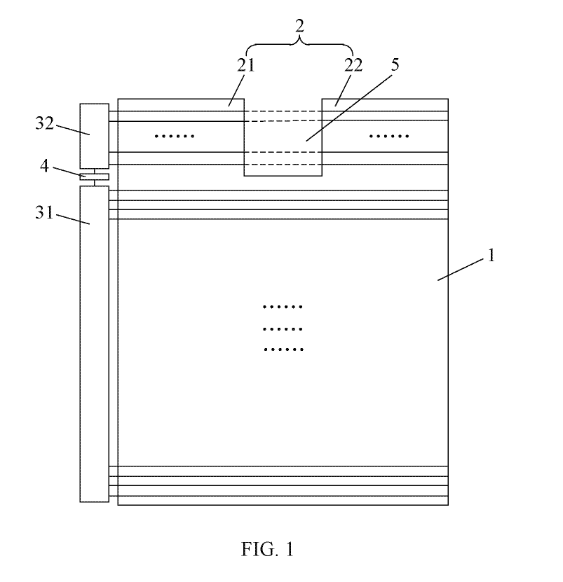

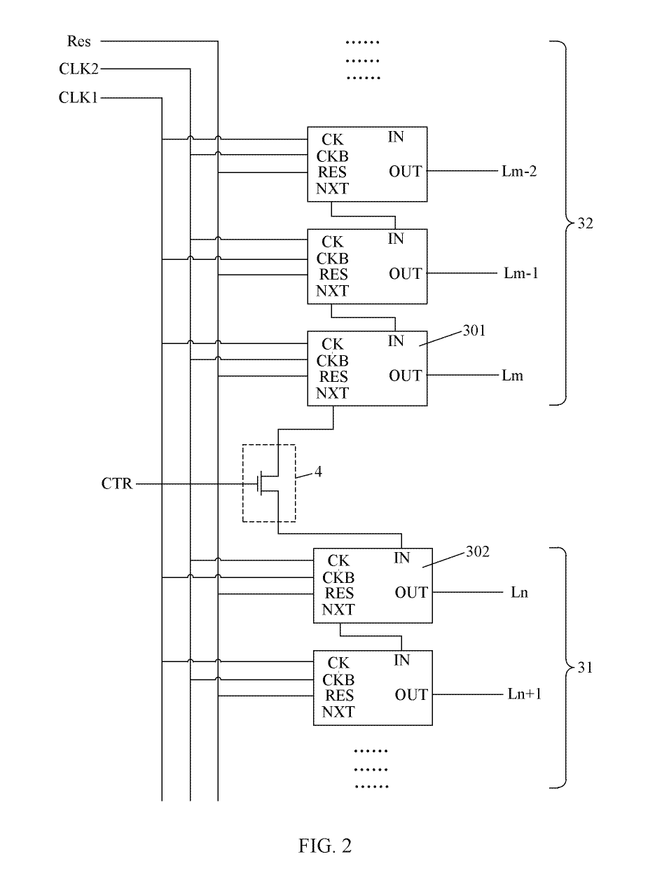

As shown in FIG. 1 and FIG. 2, FIG. 1 is a structural schematic diagram of a display panel in an embodiment of the present disclosure, FIG. 2 is a schematic diagram of a connection of a scan driving circuit in FIG. 1. An embodiment of the present disclosure provides a display panel, including: a first display area 1 and a second display area 2 protruding from the first display area 1. A display unit (not shown in FIG. 1) is disposed in both the first display area 1 and the second display area 2. A first scan driving circuit 31 is provided corresponding to the display area 1, the first scan driving circuit 31 includes cascaded multiple stages of shift registers, and an output end of each stage of the shift register of the first scan driving circuit 31 is electrically connected with the display unit in the first display area 1. A second scan driving circuit 32 is provided corresponding to the second display area 2, the second scan driving circuit 32 includes cascaded multiple stages of shift registers, and an output end of each stage of the shift register of the second scan driving circuit 32 is electrically connected with the display unit in the second display area 2. A first shift register 301 of the second scan driving circuit 32 is cascaded with a second shift register 302 of the first scan driving circuit 31 via a control unit 4, the control unit 4 is used for controlling connection/disconnection between the first shift register 301 and the second shift register 302.

The cascade connection between the shift registers means that a specific signal end of a previous stage of shift register is connected with an input end of a next stage of shift register, so that the signal of the previous stage of shift register acts as the input signal of the next stage of shift register, that is, the next stage of shift register may normally operate in response to the signal of the previous stage of shift register. For example, the first shift register 301 is the last stage of shift register of the second scan driving circuit 32, and the second shift register 302 is the first stage of shift register of the first scan driving circuit 31; or, the first shift register 301 is the first stage of shift register of the second scan driving circuit 32, and the second shift register 302 is the last stage of shift register of the first scan driving circuit 31. In the following, it is described by taking an example that the first shift register 301 is the last stage of shift register of the second scan driving circuit 32, and the second shift register 302 is the first stage of shift register of the first scan driving circuit 31. The second scan driving circuit 32 is used to provide a scan signal for the second display area 2 to drive the second display area 2 to display, the first scan driving circuit 31 is used to provide a scan signal for the first display area 1 to drive the first display area 1 to display. However, in some application scenarios, it may not be necessary that both the second display area 2 and the first display area 1 perform display. For example, the display panel may work in a first display mode and in a second display mode, the first display mode is a normal display mode, in which both the second display area 2 and the first display area 1 are may be necessary to provide a display function, therefore, in the first display mode, the control unit 4 controls to allow the first shift register 301 to be in conduction with the second shift register 302, when the second scan driving circuit 32 completes scanning, scanning by the first scan driving circuit 31 is triggered by the cascade connection between the first shift register 301 and the second shift register 302, so that both the second display area 2 and the first display area 1 perform normal display in the first display mode; the second display mode is a display mode with low power consumption, in which only the second display area 2 displays the time, system notification message or the like, while the first display area 1 does not display, therefore, in the second display mode, the control unit 4 controls to make the first shift register 301 not in conduction with the second shift register 302, when the second scan driving circuit 32 completes scanning, scanning by the first scan driving circuit 31 may not be triggered, thereby decreasing the power consumption of the display panel.

The display panel in an embodiment of the present disclosure includes a first display area, a second display area, a first scan driving circuit and a second scan driving circuit, the first shift register of the second scan driving circuit is cascaded with the second shift register of the first scan driving circuit. In the normal display mode, the control unit controls to allow the first shift register to be in conduction with the second shift register, so that the second scan driving circuit and the first scan driving circuit together complete scanning of the second display area and the first display area; in the display mode with low power consumption, the control unit controls to make the first shift register not to be in conduction with the second shift register, so that the second scan driving circuit completes scanning of the second display area alone, and it may not trigger operation of the first scan driving circuit, thereby decreasing the power consumption of the display panel.

In one embodiment, as shown in FIG. 2, a first end of the control unit 4 is electrically connected with a cascade end NXT of the first shift register 301, and a second end of the control unit 4 is electrically connected with an input end IN of the second shift register 302, the first shift register 301 is the last stage of shift register of the second scan driving circuit 32, and the second shift register 302 is the first stage of shift register of the first scan driving circuit 31.

Each stage of shift register includes an input end IN and a cascade end NXT, an the input end IN is used to receive a cascade signal of a previous stage of shift register so as to achieve the function of shift register in response to the cascade signal of the previous stage of shift register, it should be noted that, the shift register shown in FIG. 2 further includes an output end OUT for outputting the signal after the shift, for example, the output end OUT of the last stage of shift register of the second scan driving circuit 32 is connected with a scanning signal line Lm corresponding to the last row of pixel in the second display area 2, the output end OUT of the penultimate stage of shift register of the second scan driving circuit 32 is connected with a scanning signal line Lm-1 corresponding to the penultimate row of pixel in the second display area 2, the output end OUT of the antepenultimate stage of shift register of the second scan driving circuit 32 is connected with a scanning signal line Lm-2 corresponding to the antepenultimate row of pixel in the second display area 2, and so on, the output end of the i^{th} stage of shift register of the second scan driving circuit 32 is connected with a scanning signal line corresponding to the i^{th} row of pixel in the second display area 2, i is selected from 1, 2, 3, . . . , m, and m is the number of stage of all shift registers in the second scan driving circuit 32. The output end OUT of the first stage of shift register of the first scan driving circuit 31 is connected with a scanning signal line Ln corresponding to the first row of pixel in the first display area 1, the output end OUT of the second stage of shift register of the first scan driving circuit 31 is connected with a scanning signal line Ln+1 corresponding to the second row of pixel in the first display area 1, and so on, the output end OUT of the j^{th} stage of shift register of the first scan driving circuit 31 is connected with a scanning signal line corresponding to the j^{th} row of pixel in the first display area 1, j is selected from 1, 2, 3, . . . , N, and N is the number of stage of all shift registers in the first scan driving circuit 31. In FIG. 2, for both in the second scan driving circuit 32 and the first scan driving circuit 31, each stage of shift register includes a cascade end NXT and an output end OUT, the cascade end NXT is used to separately connected with a next stage of shift register, while the output end OUT is used to separately output the shift signal; in other implementations, the cascade end and the output end of the shift register may be the same end, i.e., the input end of the next stage of shift register is connected with the output end of the previous stage of shift register, the output end of the previous stage of shift register provides a cascade signal for the next stage of shift register while providing the shift signal, so as to drive the next stage of shift register to be in normal operation. The setting manner of the cascade end is not specifically limited in the embodiments of the present disclosure, for example, the cascade end may be a separate signal end only for generating a cascade signal, and may also be multiplexed as an output end for simultaneously generating an output signal and a cascade signal. In addition, each stage of shift register shown in FIG. 2 further includes a first clock signal end CK, a second clock signal end CKB and a reset signal end RES, the first clock signal end CK and the second clock signal end of an odd shift register and an even shift register are respectively connected with a first clock signal line CLK1 and a second clock signal line CLK2 alternately, the reset signal end RES is connected with a reset signal line Res. The first clock signal line CLK1 is used for providing the first clock signal necessary for the shift register, the second clock signal line CLK2 is used for providing the second clock signal necessary for the shift register, the first clock signal and the second clock signal are pulse square signals having the same amplitude and opposite phases, the reset signal line Res is used for providing the reset signal necessary for the shift register. In other implementations, the relation between each signal line and each shift register may be different, for example, the odd stage of shift register and the even stage of shift register are connected with the first clock signal lines CLK1 and the second clock signal line CLK2 via different manners, or, more clock signal lines are connected with the shift register, the specific implementing manner is related to the circuit structure of the shift register, the structure shown in FIG. 2 is merely an example, the embodiment of the present disclosure does not limit which signal ends the shift register has and how the signal ends are connected, as long as the function of the shift register can be realized.

In one embodiment, as shown in FIG. 2, the control unit 4 includes a control switch, a control end of the control switch is electrically connected with a control signal end CTR, a first end of the control switch is electrically connected with the cascade end NXT of the first shift register 301, and a second end of the control switch is electrically connected with the input end IN of the second shift register 302.

When the control signal end CTR provides an enable signal, the control switch is turned on, so that the cascade end NXT of the first shift register 301 is in conduction with the input end IN of the second shift register 302, when the control signal end CTR provides a non-enable signal, the control switch is turned off, so that the cascade end NXT of the first shift register 301 is not in conduction with the input end IN of the second shift register 302. When the control switch is an N-type transistor, the enable signal is a high-level signal and the non-enable signal is a low-level signal; when the control switch is a P-type transistor, the enable signal is a low-level signal and the non-enable signal is a high-level signal.

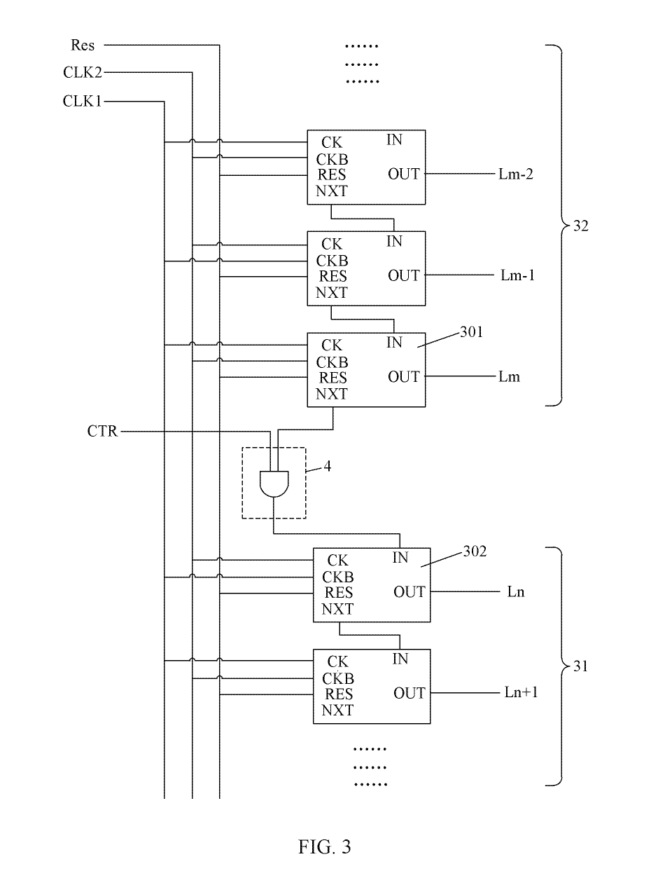

In one embodiment, as shown in FIG. 3, FIG. 3 is a schematic diagram of another connection of a scan driving circuit in FIG. 1. The control unit includes an AND gate, a first input end of the AND gate is electrically connected with the control signal end CTR, a second input end of the AND gate is electrically connected with the cascade end NXT of the first shift register 301, an output end of the AND gate is electrically connected with the input end IN of the second shift register 302.

When a high-level is the cascade signal necessary for the shift register, if the control signal end CTR provides a high-level, when the cascade end NXT of the first shift register 301 outputs low-level, the output end of the AND gate also outputs low-level, and when the cascade end NXT of the first shift register 301 outputs high-level, the output end of the AND gate also outputs high-level, i.e., it can be achieved that the signal of the cascade end NXT of the first shift register 301 is transmitted to the input end IN of the second shift register 302; if the control signal end CTR provides a low-level, the output end of the AND gate outputs low-level whenever the cascade end NXT of the first shift register 301 outputs high-level or low-level, i.e., the cascade end NXT of the first shift register 301 is not in conduction with the input end IN of the second shift register 302.

In one embodiment, as shown in FIG. 1, the second display area 2 includes a first sub display area 21 and a second sub display area 22. The first sub display area 21 and the second sub display area 22 are separated by a non-display area 5.

The non-display area 5 is a grooved area of the display panel so as to provide elements such as camera or receiver in this area. In a structure in which the second display area 2 includes a first sub display area 21 and a second sub display area 22, a first scan driving circuit 31 and a second scan driving circuit 32 may be provided only at one side of the display panel, the second scan driving circuit 32 is connected with a plurality of scanning lines, and each scanning line is connected with the first sub display area 21 and the second sub display area 22. Since the wiring cannot be implemented due to the absence of the display panel in the non-display area 5, the wiring of the scanning line between the first sub display area 21 and the second sub display area 22 can be implemented in the display panel below the non-display area 5, so that the scanning line can bypass the non-display area 5 to connect the first sub display area 21 with the second sub display area 22, the first scan driving circuit 31 and the second scan driving circuit 32 may be disposed at the same side of the display area 5, the dotted line merely indicates the connection relation between the scanning lines in the first sub display area 21 and the second sub display area 22, which does not represent the actual position of the scanning lines.

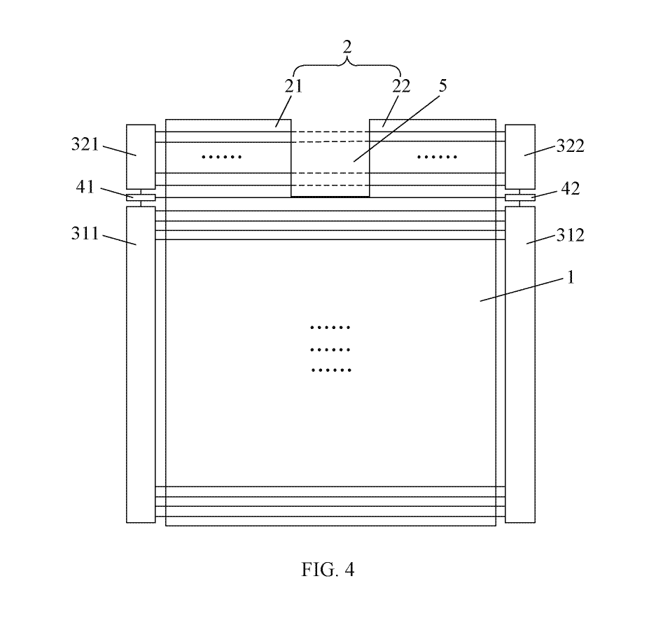

In one embodiment, as shown in FIG. 4, FIG. 4 is a structural schematic diagram of another display panel according to an embodiment of the present disclosure. The first scan driving circuit includes a first sub scan driving circuit 311 and a second sub scan driving circuit 312, the second scan driving circuit includes a third sub scan driving circuit 321 and a fourth sub scan driving circuit 322, the control unit includes a first control unit 41 and a second control unit 42. Each of the third sub scan driving circuit 321, the fourth sub scan driving circuit 322, the first sub scan driving circuit 311 and the second sub scan driving circuit 312 includes cascaded multiple stages of shift registers. The first shift register of the third sub scan driving circuit 321 is cascaded with the second shift register of the first sub scan driving circuit 311 via the first control unit 41, the first control unit is used for controlling connection/disconnection between the first shift register of the third sub scan driving circuit and the second shift register of the first sub scan driving circuit; the first shift register of the fourth sub scan driving circuit is cascaded with the second shift register of the second sub scan driving circuit via the second control unit, the second control unit is used for controlling connection/disconnection between the first shift register of the fourth sub scan driving circuit and the second shift register of the second sub scan driving circuit. In the third sub scan driving circuit 321, the first shift register is the last stage of shift register. In the fourth sub scan driving circuit 322, the first shift register is the last stage of shift register. In the first sub scan driving circuit 311, the second shift register is the first stage of shift register. In the second sub scan driving circuit 312, the second shift register is the first stage of shift register.

The third sub scan driving circuit 321 and the fourth sub scan driving circuit 322 together provide a scan signal to the second display area 2 so as to drive the second display area 2 to display. The first sub scan driving circuit 311 and the second sub scan driving circuit 312 provide a scan signal to the first display area 1 so as to drive the first display area 1 to display. When the display panel operates in the first display mode, the first control unit 41 controls the first shift register of the third sub scan driving circuit 321 to be in conduction with the second shift register of the first sub scan driving circuit 311, meanwhile the second control unit 42 controls the first shift register of the fourth sub scan driving circuit 322 to be in conduction with the second shift register of the second sub scan driving circuit 312, so that under driven of the third sub scan driving circuit 321, the fourth sub scan driving circuit 322, the first sub scan driving circuit 311, and the second sub scan driving circuit 312, both the first display area 1 and the second display area 2 perform normal display; when the display panel operates in the second display mode, the first control unit 41 controls the first shift register of the third sub scan driving circuit 321 not to be in conduction with the second shift register of the first sub scan driving circuit 311, meanwhile the second control unit 42 controls the first shift register of the fourth sub scan driving circuit 322 not to be in conduction with the second shift register of the second sub scan driving circuit 312, so that after the third sub scan driving circuit 321 and the fourth sub scan driving circuit 322 drive the second display area 2 to display, the first sub scan driving circuit 311 and the second sub scan driving circuit 312 may not be triggered to work, thereby decreasing the power consumption of the display panel.

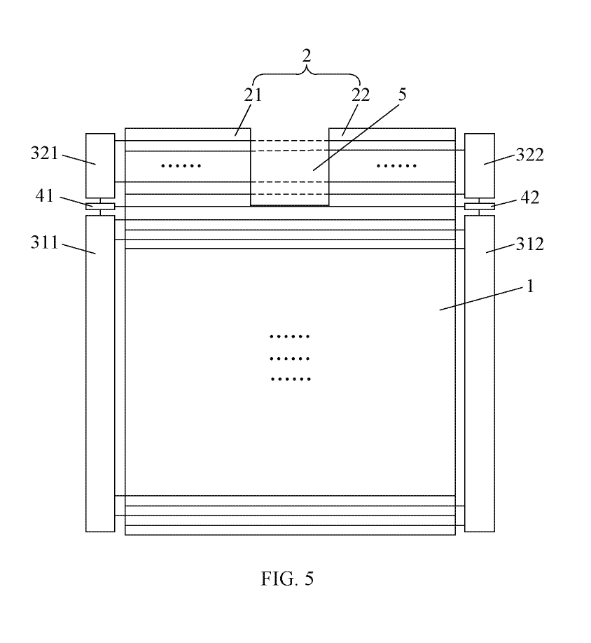

It should be noted that, there are two driving manners for driving the display area at two opposite sides of the display area by a scan driving circuit having two sub scan driving circuits, one of which is a dual-side driving manner and the other of which is a cross-driving manner. As shown in FIG. 4, both the second display area 2 and the first display area 1 belong to the dual-side driving structure. As for the second display area 2, both the output end of the first stage of shift register of the third sub scan driving circuit 321 and the output end of the first stage of shift register of the fourth sub scan driving circuit 322 are connected with the scanning line corresponding to the first row of pixel, both the output end of the second stage of shift register of the third sub scan driving circuit 321 and the output end of the second stage of shift register of the fourth sub scan driving circuit 322 are connected with the scanning line corresponding to the second row of pixel, and so on, the output end of the i^{th} stage of shift register of the third sub scan driving circuit 321 and the output end of the i^{th} stage of shift register of the fourth sub scan driving circuit 322 are connected with the scanning line corresponding to the i^{th} row of pixel. Similarly, as for the first display area 1, the output end of the j^{th} stage of shift register of the first sub scan driving circuit 311 and the output end of the j^{th} stage of shift register of the second sub scan driving circuit 312 are connected with the scanning line corresponding to the i^{th} row of pixel. As shown in FIG. 5, FIG. 5 is a structural schematic diagram of still another display panel according to an embodiment of the present disclosure. Both the second display area 2 and the first display area 1 belong to the cross-driving structure. For example, as for the second display area 2, the output end of each shift register of the third sub scan driving circuit 321 is respectively connected with the scanning line corresponding to an odd row of pixel, and the output end of each shift register of the fourth sub scan driving circuit 322 is respectively connected with the scanning line corresponding to an even row of pixel. The third sub scan driving circuit 321 is used to drive the odd row of pixel in the second display area 2, and the fourth sub scan driving circuit 322 is used to drive the even row of pixel in the second display area 2. Similarly, as for the first display area 1, the output end of each shift register of the first sub scan driving circuit 311 is respectively connected with the scanning line corresponding to an odd row of pixel, and output end of each shift register of the second sub scan driving circuit 312 is respectively connected with the scanning line corresponding to an even row of pixel. The first sub scan driving circuit 311 is used to drive the odd row of pixel in the first display area 1, and the second sub scan driving circuit 312 is used to drive the even row of pixel in the first display area 1. The manner in which the scan driving circuit located at two opposite sides of the display area drives the display area is not limited by the embodiments of the present disclosure, it is possible to be the dual-side driving manner, or it is also possible to be the cross-driving manner. Comparing the dual-side driving structure shown in FIG. 4 and the single-side driving structure shown in FIG. 1, since the dual-side driving provides the same scanning signal to two ends of the scanning line, so the problem of voltage drop in the scanning line along the scanning line extending direction caused by the single-side driving structure can be avoided in a certain extent. Compared with the single-side driving structure shown in FIG. 1, on the one hand, the cross-driving structure shown in FIG. 5 can make the space respectively occupied by the sub scan driving circuits at two sides of the display panel to be the same so as to facilitate symmetrical border design, and on the other hand, since different scanning lines correspond to different signal transmission directions, so the cross-driving structure shown in FIG. 5 can compensate the display defect caused by the voltage drop in the scanning line in the single-side driving structure in a certain extent.

In one embodiment, as shown in FIG. 4 or FIG. 5, the control end of the first control unit 41 and the control end of the second control unit 42 are electrically connected with the same control signal end.

In the structure shown in FIG. 4 or FIG. 5, the working processes and principles of the first control unit 41 and the second control unit 42 are the same. Therefore, the control ends of the two can be connected with the same control signal end so as to decrease the number of the control signal end.

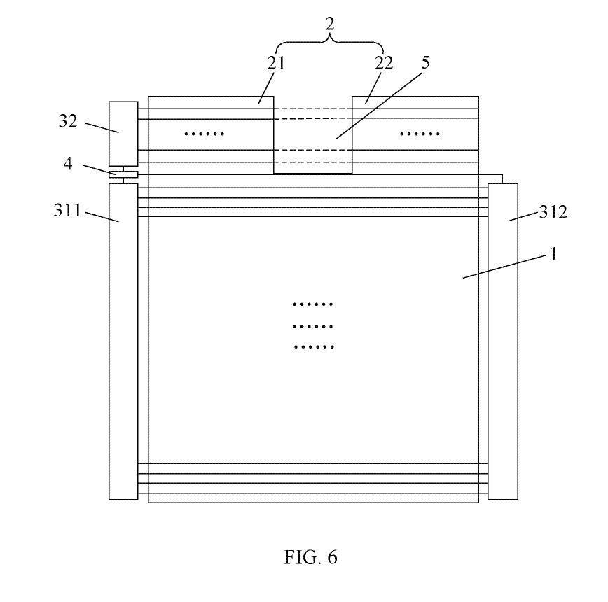

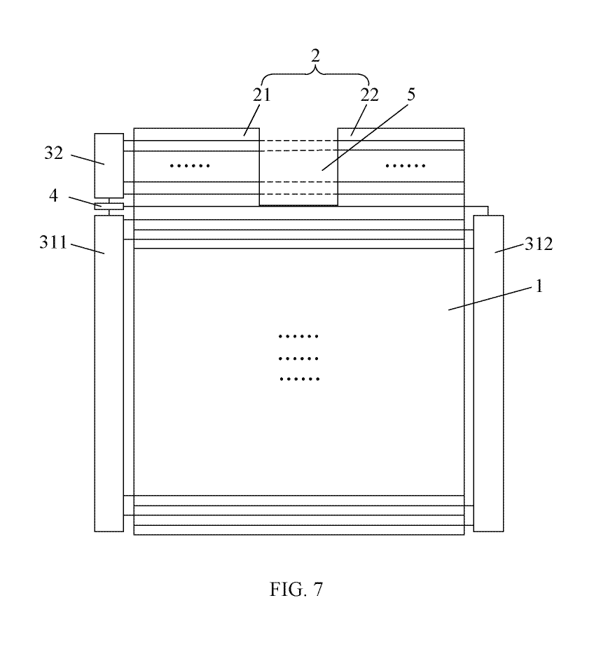

In one embodiment, as shown in FIG. 6 and FIG. 7, FIG. 6 is a structural schematic diagram of still another display panel according to an embodiment of the present disclosure, FIG. 7 is a structural schematic diagram of still another display panel according to an embodiment of the present disclosure. The first scan driving circuit includes a first sub scan driving circuit 311 and a second sub scan driving circuit 312. The first shift register of the second scan driving circuit 32 is electrically connected with the second shift register of the first sub scan driving circuit 311 via the control unit 4, the first shift register of the second scan driving circuit 32 is electrically connected with the second shift register of the second sub scan driving circuit 312 via the control unit 4.

As shown in FIG. 6, as for the first display area 1, the dual-side driving structure is adopted, the output end of the j^{th} stage of shift register of the first sub scan driving circuit 311 and the output end of the j^{th} stage of shift register of the second sub scan driving circuit 312 are connected with the scanning line corresponding to the j^{th} row of pixel. As for the second display area 2, the single-side driving structure is adopted, i.e., all scanning lines are connected to a second scan driving circuit 32 having only one sub scan driving circuit. As shown in FIG. 7, as for the first display area 1, the cross-driving structure is adopted, for example, the first sub scan driving circuit 311 is connected with the scanning line corresponding to the odd row of pixel, and the second sub scan driving circuit 312 is connected with the scanning line corresponding to the even row of pixel. As for the second display area 2, the single-side driving structure is adopted, i.e., all scanning lines are connected with a second scan driving circuit 32 having only one sub scan driving circuit. As for the display panel shown in FIG. 6 and FIG. 7, in the first display mode, after the second scan driving circuit 32 completes scanning, the first sub scan driving circuit 311 and the second sub scan driving circuit 312 may be triggered by the control unit 4 to perform scanning, so that both the second display area 2 and the first display area 1 can perform normal display; in the second display mode, only the second display area 2 displays the time, system notification message or the like, while the first display area 1 does not display, therefore, under the action of the control unit, after the second scan driving circuit 32 completes scanning, the first sub scan driving circuit 311 and the second sub scan driving circuit 312 may not be triggered to perform scanning, thereby decreasing the power consumption of the display panel. Since the first display area 1 acts as a main display area and its display area is usually larger than that of the second display area 2, so the dual-side driving or the cross-driving can be adopted for keeping the display effect of the first display area 1, as for the second display area 2, since its display area is smaller, the single-side driving can be adopted, which can satisfy the display effect of the second display area 2 and also save space.

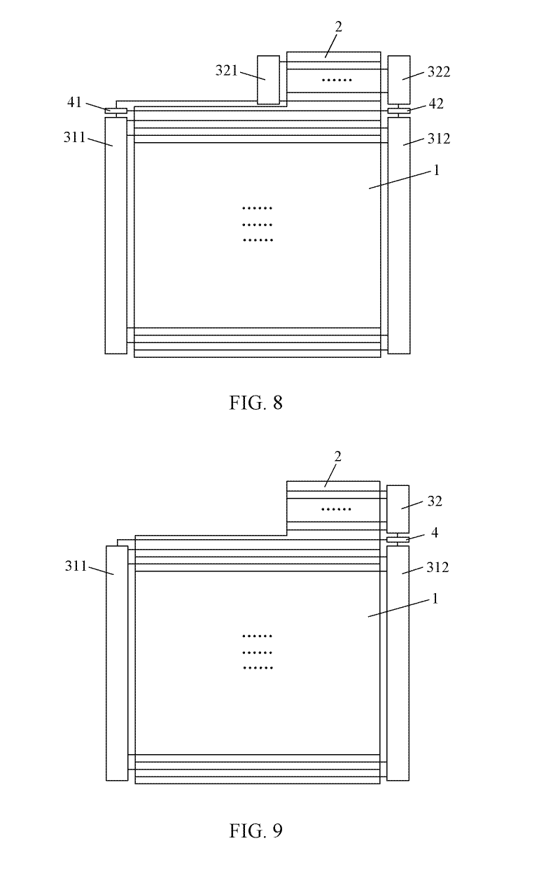

It should be noted that, the above is described by merely using a display panel having a second display area with two sub display areas as an example, and the following may be described by using a display panel having a second display area with only one sub display area as an example. As shown in FIG. 8, FIG. 8 is a structural schematic diagram of still another display panel according to an embodiment of the present disclosure. The display panel includes a second display area 2 having only one sub display area protruding from a first display area 1. Both the second display area 2 and the first display area 1 belong to the cross-driving structure, for example, as for the second display area 2, the output end of each shift register of the third sub scan driving circuit 321 is respectively connected with the scanning line corresponding to the odd row of pixel, and the output end of each shift register of the fourth sub scan driving circuit 322 is respectively connected with the scanning line corresponding to the even row of pixel, the third sub scan driving circuit 321 is used to drive the odd row of pixel in the second display area 2, and the fourth sub scan driving circuit 322 is used to drive the even row of pixel in the second display area 2. Similarly, as for the first display area 1, the output end of each shift register of the first sub scan driving circuit 311 is respectively connected with the scanning line corresponding to the odd row of pixel, and the output end of each shift register of the second sub scan driving circuit 312 is respectively connected with the scanning line corresponding to the even row of pixel, the first sub scan driving circuit 311 is used to drive the odd row of pixel in the first display area 1, and the second sub scan driving circuit 312 is used to drive the even row of pixel in the first display area 1. As shown in FIG. 9, FIG. 9 is a structural schematic diagram of still another display panel according to an embodiment of the present disclosure. The display panel includes a second display area 2 having only one sub display area protruding from a first display area 1. As for the first display area 1, the cross-driving structure is adopted, for example, the first sub scan driving circuit 311 is connected with the scanning line corresponding to the odd row of pixel, and the second sub scan driving circuit 312 is connected with the scanning line corresponding to the even row of pixel. As for the second display area 2, the single-side driving structure is adopted, i.e., all scanning lines are connected to a second scan driving circuit 32 having only one sub scan driving circuit. Since the first display area 1 acts as a main display area and its display area is usually larger than that of the second display area 2, so the dual-side driving or the cross-driving can be adopted for keeping the display effect of the first display area 1, as for the second display area 2, since its display area is smaller, the single-side driving can be adopted, which can satisfy the display effect of the second display area 2 and also save space.

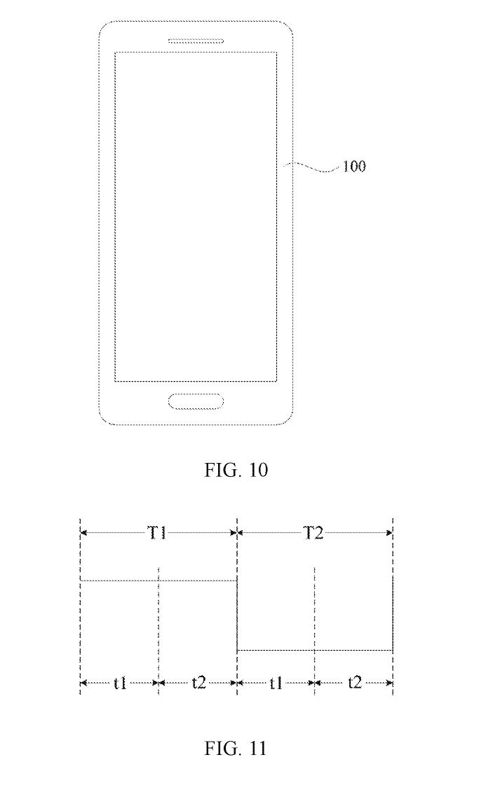

As shown in FIG. 10, FIG. 10 is a structural schematic diagram of a display device according to an embodiment of the present disclosure. An embodiment of the present disclosure provides a display device including the above-described display panel 100.

The specific structure and principle of the display panel are the same as those in the above embodiments, which may not be further described herein. The display device may be any electronic device having a display function such as a touch screen, a cellphone, a tablet computer, a notebook computer or a television.

The display device in the embodiment of the present disclosure includes a first display area, a second display area, a first scan driving circuit and a second scan driving circuit, the first shift register of the second scan driving circuit is cascaded with the second shift register of the first scan driving circuit, in the normal display mode, the control unit controls to allow the first shift register to be in conduction with the second shift register, so that the second scan driving circuit and the first scan driving circuit together complete scanning of the second display area and the first display area, in the display mode with low power consumption, the control unit controls to make the first shift register not to be not in conduction with the second shift register, so that the second scan driving circuit completes scanning of the second display area alone, and it may not trigger operation of the first scan driving circuit, thereby decreasing the power consumption of the display panel.

As shown in FIG. 11, FIG. 11 is a sequence diagram of a control signal of a control unit in an embodiment of the present disclosure. An embodiment of the present disclosure provides a scan driving method for the above-described display panel, and the method may be described by taking an example of structures shown in FIG. 1 and FIG. 2. The method includes:

In the first display mode T1, the control unit 4 controls to allow the first shift register 301 to be in conduction with the second shift register 302, so that after the second scan driving circuit 32 completes scanning, scanning by the first scan driving circuit 31 is triggered by the control unit 4, and thus both the second display area 2 and the first display area 1 can perform normal display in the first display mode T1; the high-level shown in FIG. 11 represents a control signal for triggering the control unit 4 to control the first shift register 301 to be in conduction with the second shift register 302, and the low-level represents a control signal for triggering the control unit 4 to control the first shift register 301 not to be in conduction with the second shift register 302;

In the second display mode T2, the control unit 4 controls the first shift register 301 not to be in conduction with the second shift register 302, so that after the second scan driving circuit 32 completes scanning, scanning by the first scan driving circuit 31 may not be triggered, thereby decreasing the power consumption of the display panel.

The working process and principle of the display panel are the same as those in the above embodiments, which will not be further described herein.

As for the scan driving method in the embodiments of the present disclosure, the first shift register of the second scan driving circuit is cascaded with the second shift register of the first scan driving circuit, in the normal display mode, the control unit controls to allow the first shift register to be in conduction with the second shift register, so that the second scan driving circuit and the first scan driving circuit together complete scanning of the second display area and the first display area; in the display mode with low power consumption, the control unit controls to make the first shift register not in conduction with the second shift register, so that the second scan driving circuit completes scanning of the second display area alone, and it may not trigger operation of the first scan driving circuit, thereby decreasing the power consumption of the display panel.

In one embodiment, as shown in FIG. 11, the first display mode T1 includes a first stage t1 and a second stage t2, and the second display mode T2 includes a first stage t1 and a second stage t2. During the first stage t1 in the first display mode T1, the second scan driving circuit 32 performs scan driving; during the second stage t2 in the first display mode T1, the first scan driving circuit 31 performs scan driving; during the first stage t1 in the second display mode T2, the second scan driving circuit 32 performs scan driving; during the second stage t2 in the second display mode T2, each shift register of the first scan driving circuit 31 outputs a non-enable signal.

In the first display mode T1, both the second scan driving circuit 32 and the first scan driving circuit 31 perform normal scan driving; in the second display mode T2, the second scan driving circuit 32 performs scan driving during the first stage t1, and neither the first scan driving circuit 31 nor the second scan driving circuit 32 performs scan driving during the second stage t2, thereby decreasing the power consumption of the display panel. Taking a specific display panel structure as an example, assuming that 160 rows of pixel correspond to the second display area 2, and 2560 rows of pixel correspond to the first display area 1, the duration of each frame is 16.7 ms, and each frame includes a first stage t1 and a second stage t2, in the second display mode T2, the duration corresponding to the first stage t1 is

$$\frac{160}{160 + 2560} \times 16.7 ms = 0.98 ms ,$$

the duration corresponding to the second stage t2 is 15.72 ms, since the first scan driving circuit 31 does not perform scan driving during the second stage t2. Compared with the first display mode T1, the power consumption of the second display mode T2 is decreased to 5.8%.

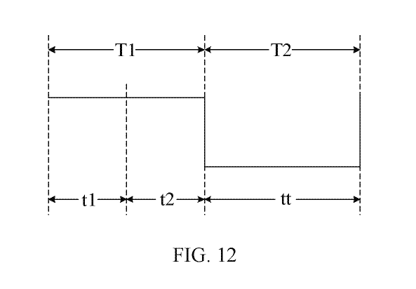

In one embodiment, as shown in FIG. 12, FIG. 12 is another sequence diagram of a control signal of a control unit in an embodiment of the present disclosure. The first display mode T1 includes a first stage t1 and a second stage t2. During the first stage t1, the second scan driving circuit 32 performs scan driving, and during the second stage t2, the first scan driving circuit 31 performs scan driving. The second display mode T2 includes a scan stage tt which is periodic and continuous, during the scan stage tt, the second scan driving circuit 32 performs scan driving.

The control method corresponding to the sequence shown in FIG. 12 is different from the control method corresponding to the sequence shown in FIG. 11 in the second display mode T2. In the sequence shown in FIG. 11, each frame in the second mode T2 is divided into a first stage t1 and a second stage t2, the scanning for the second display area 2 is performed during the first stage t1, and no scanning is performed in the second stage t2; in the sequence shown in FIG. 12, each frame in the second mode T2 is scanning time for the second display area 2, that is, the second scan driving circuit 32 can directly perform a next scanning after completing one scanning for the second display area 2, compared with the method corresponding to the sequence shown in FIG. 11, when the same refresh rate is used, the total scanning time for the second display area 2 is increased, so the charging time corresponding to each row of pixel is increased, which improves the pixel charging effect.

Finally, it should be noted that, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel having a first display area and a second display area protruding from the first display area, comprising:
a display unit placed in both the first display area and the second display area;
a first scan driving circuit corresponding to the first display area, the first scan driving circuit comprising cascaded multiple stages of shift registers, and an output end of each stage of shift register of the first scan driving circuit being electrically connected with the display unit in the first display area;
a second scan driving circuit corresponding to the second display area, the second scan driving circuit comprising cascaded multiple stages of shift registers, and an output end of each stage of shift register of the second scan driving circuit being electrically connected with the display unit in the second display area; and
a control unit, a first shift register of the second scan driving circuit being cascaded with a second shift register of the first scan driving circuit via the control unit, and the control unit being configured to control connection/disconnection between the first shift register and the second shift register.

2. The display panel according to claim 1, wherein
a first end of the control unit is electrically connected with a cascade end of the first shift register, and a second end of the control unit is electrically connected with an input end of the second shift register, the first shift register is a last stage of shift register of the second scan driving circuit, the second shift register is a first stage of shift register of the first scan driving circuit.

3. The display panel according to claim 2, wherein
the control unit comprises a control switch, a control end of the control switch is electrically connected with a control signal end, a first end of the control switch is electrically connected with the cascade end of the first shift register, and a second end of the control switch is electrically connected with the input end of the second shift register.

4. The display panel according to claim 2, wherein
the control unit comprises an AND gate, a first input end of the AND gate is electrically connected with a control signal end, a second input end of the AND gate is electrically connected with the cascade end of the first shift register, and an output end of the AND gate is electrically connected with the input end of the second shift register.

5. The display panel according to claim 1, wherein
the second display area comprises a first sub display area and a second sub display area, and the first sub display area and the second sub display area are separated by a non-display area.

6. The display panel according to claim 1, wherein
the first scan driving circuit comprises a first sub scan driving circuit and a second sub scan driving circuit, the second scan driving circuit comprises a third sub scan driving circuit and a fourth sub scan driving circuit, and the control unit comprises a first control unit and a second control unit;
a first shift register of the third sub scan driving circuit is cascaded with a second shift register of the first sub scan driving circuit via the first control unit, and the first control unit is configured to control connection/disconnection between the first shift register of the third sub scan driving circuit and the second shift register of the first sub scan driving circuit; and
a first shift register of the fourth sub scan driving circuit is cascaded with a second shift register of the second sub scan driving circuit via the second control unit, and the second control unit is configured to control connection/disconnection between the first shift register of the fourth sub scan driving circuit and the second shift register of the second sub scan driving circuit.

7. The display panel according to claim 6, wherein
a control end of the first control unit and a control end of the second control unit are electrically connected with the same control signal end.

8. The display panel according to claim 1, wherein
the first scan driving circuit comprises a first sub scan driving circuit and a second sub scan driving circuit;
the first shift register of the second scan driving circuit is electrically connected with a second shift register of the first sub scan driving circuit via the control unit, and the first shift register of the second scan driving circuit is electrically connected with a second shift register of the second sub scan driving circuit via the control unit.

9. A display device comprising a display panel, the display panel has a first display area and a second display area protruding from the first display area, and the display panel comprises:
a display unit placed in both the first display area and the second display area;
a first scan driving circuit corresponding to the first display area, the first scan driving circuit comprising cascaded multiple stages of shift registers, and an output end of each stage of shift register of the first scan driving circuit being electrically connected with the display unit in the first display area;
a second scan driving circuit corresponding to the second display area, the second scan driving circuit comprising cascaded multiple stages of shift registers, and an output end of each stage of shift register of the second scan driving circuit being electrically connected with the display unit in the second display area; and
a control unit, a first shift register of the second scan driving circuit being cascaded with a second shift register of the first scan driving circuit via the control unit, and the control unit being configured to control connection/disconnection between the first shift register and the second shift register.

10. A scan driving method for a display panel, wherein the display panel comprises:
a display unit placed in both the first display area and the second display area;
a first scan driving circuit corresponding to the first display area, the first scan driving circuit comprising cascaded multiple stages of shift registers, and an output end of each stage of shift register of the first scan driving circuit being electrically connected with the display unit in the first display area;
a second scan driving circuit corresponding to the second display area, the second scan driving circuit comprising cascaded multiple stages of shift registers, and an output end of each stage of shift register of the second scan driving circuit being electrically connected with the display unit in the second display area; and
a control unit, a first shift register of the second scan driving circuit being cascaded with a second shift register of the first scan driving circuit via the control unit, and the control unit being configured to control connection/disconnection between the first shift register and the second shift register,
the scan driving method comprises:
controlling, by the control unit in a first display mode, the first shift register to be in conduction with the second shift register;
controlling, by the control unit in a second display mode, the first shift register not to be in conduction with the second shift register.

11. The method according to claim 10, wherein
the first display mode comprises a first stage and a second stage, and the second display mode comprises a first stage and a second stage;
during the first stage of the first display mode, the second scan driving circuit performs scan driving;
during the second stage of the first display mode, the first scan driving circuit performs scan driving;
during the first stage of the second display mode, the second scan driving circuit performs scan driving;
during the second stage of the second display mode, each shift register of the first scan driving circuit outputs a non-enable signal.

12. The method according to claim 10, wherein
the first display mode comprises a first stage and a second stage, during the first stage, the second scan driving circuit performs scan driving, during the second stage, the first scan driving circuit performs scan driving;
the second display mode comprises a scan stage which is periodic and continuous, during the scan stage, the second scan driving circuit performs scan driving.
